(19) United States
(12) Patent Application Publication
(10) Pub. No.: US 2003/0061991 A1
(43) Pub. Date: Apr. 3, 2003

(54) Protective shield and system for gas distribution

(75) Inventors: Colby Mattson, Santa Cruz, CA (US); Iraj Hakimelahy, Scotts Valley, CA (US); Larry D. Bartholomew, Felton, CA (US); Seung Gyun Park, Felton, CA (US); Soon K. Yuh, Scotts Valley, CA (US)

Correspondence Address: DORSEY & WHITNEY, INTELLECTUAL PROPERTY DEPARTMENT, 1001 PENNSYLVANIA AVE., N.W., SUITE 300 SOUTH, WASHINGTON, DC, 20004, US

(73) Assignee: ASML US, INC.

(21) Appl. No.: 10/226,459

(22) Filed: Aug. 23, 2002

Related U.S. Application Data
(60) Provisional application No. 60/314,762, filed on Aug. 24, 2001.

(51) Int. Cl. C23C 16/00

(52) U.S. Cl. 118/715

(57) ABSTRACT

A protective shield and system for gas distribution are provided for reducing film and process byproduct deposition on surfaces of a Chemical Vapor Deposition system. In one embodiment, the present invention provides a volume insert within the inert gas shield plenum which reduces byproduct deposition buildup on the shield. In another embodiment, the present invention provides vent guide for directing gaseous deposition byproducts to the center of a vent passageway, thus reducing particle deposits on the walls of the vent system. In another embodiment the present invention provides partial plugs installed in the injector purge passageway for the purpose of redirecting and metering inert gas, thus reducing byproduct deposition on the shield and at the ends of the injectors. In another embodiment, the present invention provides a CVD system having a full volume vent assembly with a large capacity for powder buildup, thereby enhancing the runtime before cleaning maintenance is required.

### RELATED APPLICATIONS

The present invention claims the benefit of U.S. provisional patent application Serial no. 60/314,762 filed Aug. 24, 2001, the entire disclosure of which is hereby incorporated by reference.

### FIELD OF THE INVENTION

The present invention relates generally to gas distribution systems and more particularly to a chemical vapor deposition system having a gas shield for reducing film and process byproduct deposition on surfaces of the system.

### BACKGROUND OF THE INVENTION

Chemical vapor deposition (CVD) systems are well known and widely used to deposit or grow thin films of various compositions upon surfaces of substrates. For example, CVD systems are commonly used to deposit dielectric, passivation and dopant layers upon semiconductor wafers. CVD systems operate by introducing a reactive process gas or chemical vapor into a deposition chamber in which the substrate to be processed has been placed. As the vaporized material passes over the substrate it is adsorbed and reacts on the surface of the substrate to form the film. Various inert carrier gases may also be used to carry a solid or liquid source into the deposition chamber in a vapor form. Typically, the substrate is heated to catalyze the reaction.

One type of CVD system that is widely used in processing semiconductor wafers is an atmospheric pressure chemical vapor deposition system (hereinafter APCVD system). APCVD systems are described in, for example, U.S. Pat. No. 4,834,020, to Bartholomew et al., which is incorporated herein by reference. In an APCVD system, the deposition chamber is operated at atmospheric pressure while gaseous source chemicals are introduced to react and deposit a film on the substrate. One kind of APCVD system uses a belt or conveyor to move the substrates through a series of deposition chambers during the deposition process. A typical belt-driven APCVD system may have three to four separate deposition chambers. Each chamber has a linear process gas injector for introducing process gas into the chamber to process the substrates, and one or more exhaust ports for exhausting gases and byproducts from the chamber.

Linear process gas injectors are described, for example, in U.S. Pat. No. 5,683,516, to DeDontney et al., which is incorporated herein by reference. Typically, the injector has several injection ports positioned less than one inch from a surface of the substrate, and often as close as ⅛ to 1/2 inches. With this limited clearance between the injection ports and the substrate surface, the injection ports or adjacent surfaces can soon become coated with material and byproducts produced during the deposition process. Material and byproducts can also be deposited on the lower edges of the exhaust ports which are in close proximity to the wafers. Over time, these deposits accumulate, becoming a source of particles that may become embedded in the film deposited on the substrate, degrading film quality. Thus, this accumulation must be slowed or prevented.

An improvement has been made to reduce the accumulation of deposits on the injection ports and the exhaust ports of the CVD system. This approach uses a number of shields adjacent to and surrounding the injector and lower surfaces of the exhaust ports. Shields are described, for example, in U.S. Pat. No. 5,849,088, to DeDontney et al., and U.S. Pat. Nos. 6,056,824 and 6,352,592 to Bartholomew et al., which are incorporated herein by reference. Each shield typically includes a base or support body joined to a screen to form a plenum into which an inert shield gas, such as nitrogen, is introduced. The shield gas is delivered to the plenum through a conduit or metering tube having an array of holes along its length. A number of delivery lines provide shield gas to the metering tube from a gas manifold or bulkhead fitting in the APCVD system. The gas manifold in turn is connected to an external shield gas supply that is typically remotely located. The inert gas diffuses through the screens to displace and dilute the reactive process gases in the region adjacent to the shields, thereby reducing deposition on the shield itself.

While the previous shield designs provide an advance in the art, one problem with previous shield designs is deposition of oxides, silicate glass and process byproducts on the components of the shield. This is particularly a problem with shield screens, deposits on which can disrupt the flow of gases through the screen, causing imbalances in concentration of reactant or process gases in the process chamber. This in turn leads to deterioration of deposition uniformity, increasing with time until the uniformity within wafer goes out of acceptable bounds. A related problem is that because horizontal faces of shield screens protecting the injector form a ceiling of the process chamber, deposits formed thereon can flake or peel-off resulting in contamination of the film being deposited on the substrate. Another problem that can occur is deposition of oxides, glass and process byproducts in the exhaust path, and in particular in a location adjacent to the inlets to the exhaust path. Deposits are commonly formed in exhaust paths by exhausting process or reactant gases and byproducts which adhere to or condense on the relatively cool surfaces in the exhaust path. As explained above, these deposits can flake or peel-off resulting in contamination of the film being deposited on the substrate. Yet another problem with conventional APCVD systems and other oxide deposition tools using a linear injectors for depositing oxide on wafers or substrates is the frequent need to stop processing and remove the injector and vent assemblies for off-line cleaning.

Accordingly, there is a need for an apparatus and method which increases the time between scheduled cleaning of the linear injectors and adjacent CVD system components. There is a need for an apparatus which enables process uniformity (film thickness) within each wafer or between consecutive wafers or substrates to remain consistency over an increased time interval. There is a further need for an apparatus and method which reduces the build-up of by-products of the deposition on the shield and in the exhaust path in a powdery form that may flake and fall back onto the substrates or work pieces, generating high levels of defects in the films. It is desirable that the apparatus and method reduce silicate glass buildup on the injector deposition hardware to increase the effective run time between cleans, increasing the overall run time longevity. It is also desirable that the apparatus and method reduce or eliminate the aforementioned powder or glass buildup, resulting in enhanced tool or system run time.

### SUMMARY OF THE INVENTION

It is an object of the present invention to provide a gas distribution system such as a chemical vapor deposition (CVD) system having improved process uniformity and repeatability over time through the reduction or elimination of deposits on the shield, exhaust path inlet and other system components. It is a further object of the invention to provide extended operating time between scheduled maintenance or cleaning operations.

In one embodiment, the present invention provides a protective shield for gas distribution systems. The protective shield comprises a base having a unit frame formed around the perimeter of the base, a perforated sheet carried by the unit frame, a plenum partially defined by the base and the perforated sheet, a gas delivery device for delivering an inert gas to the plenum, and a volume insert disposed within the plenum for controlling the distribution of the gas flow through the horizontal and vertical sections of the perforated sheet. The provision of the volume insert within the plenum reduces the volume of the plenum for gas flow. The volume insert is disposed within the plenum such that the distribution of the gas flow through the horizontal section is appropriately balanced relative to the distribution of the gas flow through the vertical section of the perforated sheet. The volume insert can be a three-bend band. In this embodiment the three bend-band has a first surface facing the vertical section of the perforated sheet, a second surface facing the horizontal section of the perforated sheet, and a third surface facing the gas delivering device. The second surface of the three bend-band and the horizontal section of the perforated sheet form a tapered passageway for gas flow from the gas delivering device.

In another embodiment, the present invention provides a chemical vapor deposition system. The CVD system comprises an injector for injecting gaseous substances into a processing chamber and a protective shield positioned adjacent the injector for protecting the front surface of the injector. The injector includes injector plugs disposed at the ends of a chemical injection port slot to balance inert purge gas flow supplied to the ends of the chemical injection port slot relative to the chemical gas flow in the middle of the chemical injection port slot, whereby deposition and buildup of reaction byproducts on the protective shield are reduced. The injector plug can be provided with an opening varying in dimension.

In another embodiment, the present invention provides a protective shield assembly a for a gas distribution system. The protective shield assembly comprises a pair of injector shield bodies positioned adjacent an injector and spaced apart to define a port for flow of gaseous substances from the injector and a pair of vent shield bodies spaced apart from said injector shield bodies. The injector and vent shield bodies define an exhaust path inlet for exhausting unused gaseous substances and reaction byproducts. A vent guide assembly is provided for directing the unused gaseous substances and reaction byproducts from the exhaust path inlet to a vent path. The vent guide assembly comprises a first guide member coupled to the injector shield body and a second guide member coupled to the vent shield body. The first and second guide members are configured to form a curved section of the exhaust path inlet to direct the unused gaseous substances and reaction byproducts to the center of the vent path, whereby reducing deposition of unused gaseous substances and reaction byproducts on the walls of the vent path.

In a further embodiment, the present invention provides a chemical vapor deposition system having a full volume vent assembly. The CVD system comprises an injector, a shield assembly for protecting the front surface of the injector, and a full volume vent assembly for removing unused gaseous substances and reaction by-products from the reaction chamber. The full volume vent assembly encompasses substantially the full length and width of the injector body, providing a large volume for accumulation of powder from reaction by-products away from the wafers which extends the maintenance cleaning interval.

### BRIEF DESCRIPTION OF THE DRAWINGS

Other objects and advantages of the present invention will become apparent upon reading the detailed description of the invention and the appended claims provided below, and upon reference to the drawings, in which:

FIG. 1 is a schematic view of an APCVD processing system which can incorporate the new protective shield in accordance with the present invention;

FIG. 2 is a schematic view of a protective shield having a volume insert inside the injector shield frame according to one embodiment of the present invention;

FIGS. 3A-3D are a Computational Fluid Dynamic (CFD) simulation plot and graphs showing the vertical and horizontal velocity magnitude distribution of nitrogen purge gas through a prior art injector shield and the predicted silicon dioxide deposition rate;

FIGS. 4A-4D are a CFD simulation plot and graphs showing the vertical and horizontal velocity magnitude distribution of nitrogen purge gas through an injector shield and the predicted silicon dioxide deposition rate according to one embodiment of the present invention;

FIGS. 5A and 5B are CFD simulation plots showing the pressure distribution inside an injector shield having a volume insert of the present invention (FIG. 5B) as compared to a prior art injector shield (FIG. 5A);

FIGS. 6A and 6B are CFD simulation plots and respective graphs showing the reduction in intermediate chemical reaction species at the surface of the injector shield having a volume insert of the present invention (FIG. 6B) as compared to a prior art injector shield (FIG. 6A);

FIG. 7 is an exploded view of a prior art injector having a chemical plug at the ends of a chemical distribution slot;

FIG. 8 is a cross sectional view of an injector showing a plurality of passages and thin distribution channels for delivering gases and the location of the chemical plugs with partial plugs disposed at the ends of a chemical distribution channel according to one embodiment of the present invention;

FIG. 9 is a schematic view of an inner injector chemical slot having a partial plug at the end of the slot according to one embodiment of the present invention;

FIG. 10 is a schematic view of an injector partial-plug according to one embodiment of the present invention which changes the direction and magnitude of N₂ purge flow at the ends of the injector chemical slot;

FIG. 11 is a schematic view of a part of a protective shield having a vent guide assembly according to one embodiment of the present invention;

FIG. 12 is an expanded schematic view showing the detailed structure of a vent guide assembly according to one embodiment of the present invention;

FIG. 13 is a schematic view showing a chemical vapor deposition system protective shield comprising a vent guide assembly and volume insert according to one embodiment of the present invention;

FIGS. 14A and 14B are schematic views of a CVD system of the prior art (FIG. 14A) as compared to a CVD system of the present invention having a full volume vent assembly (FIG. 14B); and

FIGS. 15-16 are partial schematic views of CVD systems showing one half of the full volume vent assembly of FIG. 14B according to two embodiments of the present invention.

### DETAILED DESCRIPTION OF THE INVENTION

The present invention is directed to a method and apparatus for reducing film and process byproduct deposition on surfaces of a CVD system.

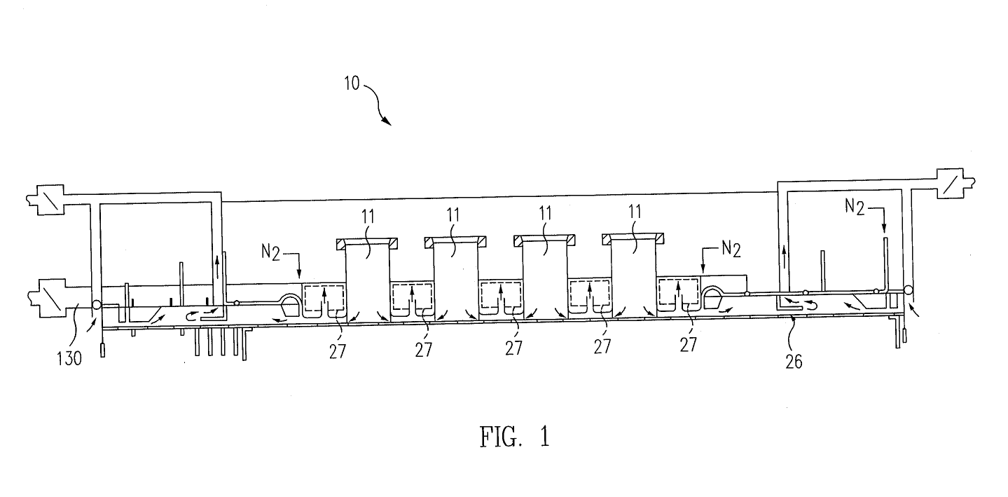

FIG. 1 schematically illustrates a section of an existing prior art CVD processing system 10 with which the protective shield assembly of this invention may be used, which is described in more detail in U.S. Pat. No. 4,834,020 the disclosure of which is hereby incorporated by reference. As is known in the art, atmospheric pressure CVD systems typically include one or more processing modules or chambers 11 positioned along the process path. Each processing module 11 includes an injector for injecting chemical reagents and other gaseous substances into a reaction chamber or process area below the injector. In the illustrated example, the CVD system 10 includes four processing modules 11 as shown in FIG. 1, although it is to be understood that the number of processing modules 11 employed depends upon the constraints of a particular process. Conduits (not shown) generally deliver the gaseous substances to the injectors, which transport the gases through separate flow paths. The substrate is transported along the process path by a conveyor.

The entire process path is enclosed within a muffle for the transport and processing of the substrate. As shown in FIG. 1, the processing modules 11 are separated by buffer modules 27 which isolate the processing modules 11 from the rest of the processing path. Buffer modules 27 may include a plurality of curtains hanging from a plenum body which is used to deliver an inert gas such as nitrogen between the curtains. Deposition waste products including unreacted gas are expelled from the reaction chambers through exhaust vents which are coupled to a suitable exhaust system (not shown). The chamber deposition area and substrate are retained at the desired reaction temperature by heating elements.

As the substrate is moved through each reaction chamber 11, the injected substances react with each other and/or with the upper surface of the substrate to form a thin, uniform layer or film. The actual reagents used in the CVD process depend in part upon the type and quality of film desired. In one application of the processing system 10 silicon source reactants such as TEOS, silane or disilane with nitrogen, and if desired a dopant source reactant such as TMPi, TMB, TEPo, TEB, phosphine and/or diborane are employed to deposit films. The reagent is typically supplied with an inert carrier gas such as nitrogen. Undoped or doped glass films are formed by reaction with oxygen and/or ozone, typically supplied through a separate port of the injector.

As mentioned above, protective shields have been employed in the prior art to reduce the accumulation of deposits on various surfaces in the CVD system. Protective shields having a construction called a “frame construction” are described in more detail in U.S. Pat. Nos. 5,849,088, 6,056,824, and 6,352,592 the disclosures of which are hereby incorporated by reference.

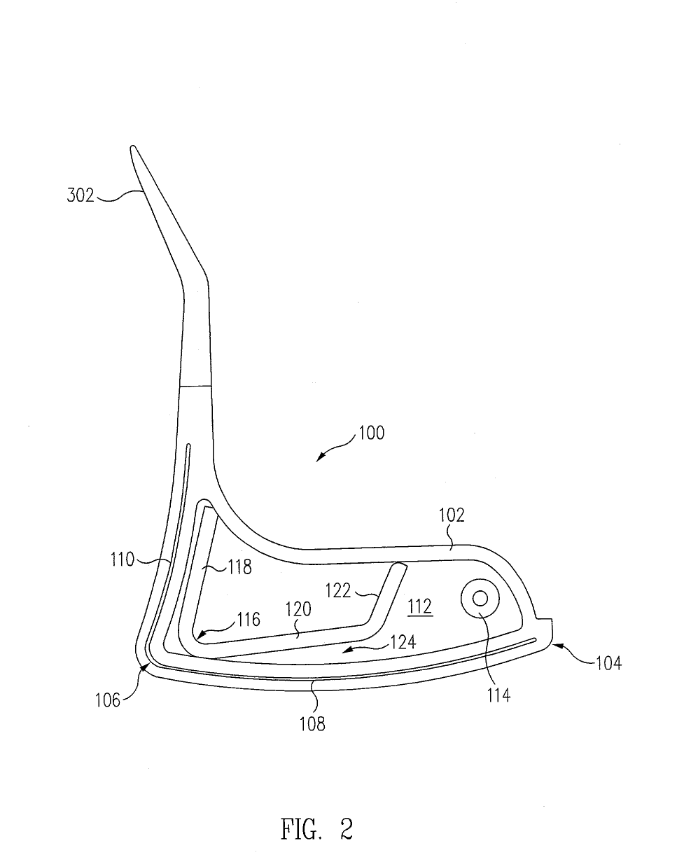

To further improve the field of protective shields in CVD processing, the present invention provides a protective shield having a volume insert or feature as shown in FIGS. 2 to 6. As shown in FIG. 2, the protective injector shield 100 comprises a base 102 having a unit frame 104 formed around the perimeter of the base 102. A perforated sheet or screen 106 is carried by the unit frame 104 of the base 102. The perforated sheet 106 comprises a horizontal section 108 facing a substrate (not shown) and a vertical section 110 facing an exhaust slot (not shown). A plenum 112 is defined by the base 102 and the vertical and horizontal sections 108 and 110 of the perforated sheet 106. A gas delivery device 114 is disposed within the plenum 112 for delivering an inert gas at a flow rate such that the gas diffuses through the perforated sheet 106. A volume insert 116 is disposed within the plenum 112 for controlling velocity of the gas flow through the horizontal and vertical sections 108 and 110 of the perforated sheet 106.

The volume insert 116, in this example sometimes called a “reduced volume insert,” is disposed within the plenum 112 such that the gas is prevented from flowing directly out the vertical section 110 of the perforated sheet 106 into the exhaust path without first being forced to flow near the horizontal section 108 of the perforated sheet 106, providing better protection of that horizontal surface 108.

Preferably the reduced volume insert 116 is a solid bend band affixed to the base 102 of the shield body by any suitable means such as welding. Alternatively, the volume insert can be an integral part of the base 102. The solid bend band reduces the internal volume of the cavity partially defined by the base 102 and perorated sheet 106. In one embodiment, the reduced volume insert 116 is a three-bend band extending longitudinally along the full length of the base. The three-bend band has a first section 118 facing and closely disposed adjacent the vertical section 110 of the perforated sheet 106, a second section 120 facing the horizontal section 108 of the perforated sheet 106, and a third section 122 facing the gas delivering device 114. The second section 120 of the three bend band 116 and the horizontal section 108 of the perforated sheet 106 forms a tapered passageway 124 for gas flow from the gas delivering device 114. Preferably, the tapered passageway 124 tapers from wide to narrow as the gas flows from the gas delivering device 114 along the horizontal section 108. In this embodiment, a thin gas channel is formed between the perforated sheet 106 and the three bend band 116 at the intersection of the first and second sections 118 and 120 of the bend band 116. By controlling the gas flow from the gas delivering device 114 the velocity of gas flow diffused through the horizontal and vertical sections 108 and 110 of the perforated sheet 106 is controlled.

Preferably the protective injector shield 100 further comprises a vent guide member 302 for directing unused gaseous substances and reaction byproducts to the center of a vent passageway, and thus reducing particle deposits on the walls of the vent system. The vent guide member is coupled to the base of the shield body and extends upwardly and outwardly to the vent passageway. The vent guide member can be coupled to the base by any means such as welding. Alternatively the vent guide member is an integral part of the base of the shield body. Preferably the vent guide member bends outwardly at angle between about 10 to 30 degrees with respect to a vertical axis. By providing a reduced volume insert within the shield injector frame cavity, the purge inert gas is more effectively channeled to exit the horizontal face of the screen and prevent heavy glass deposition on the screen.

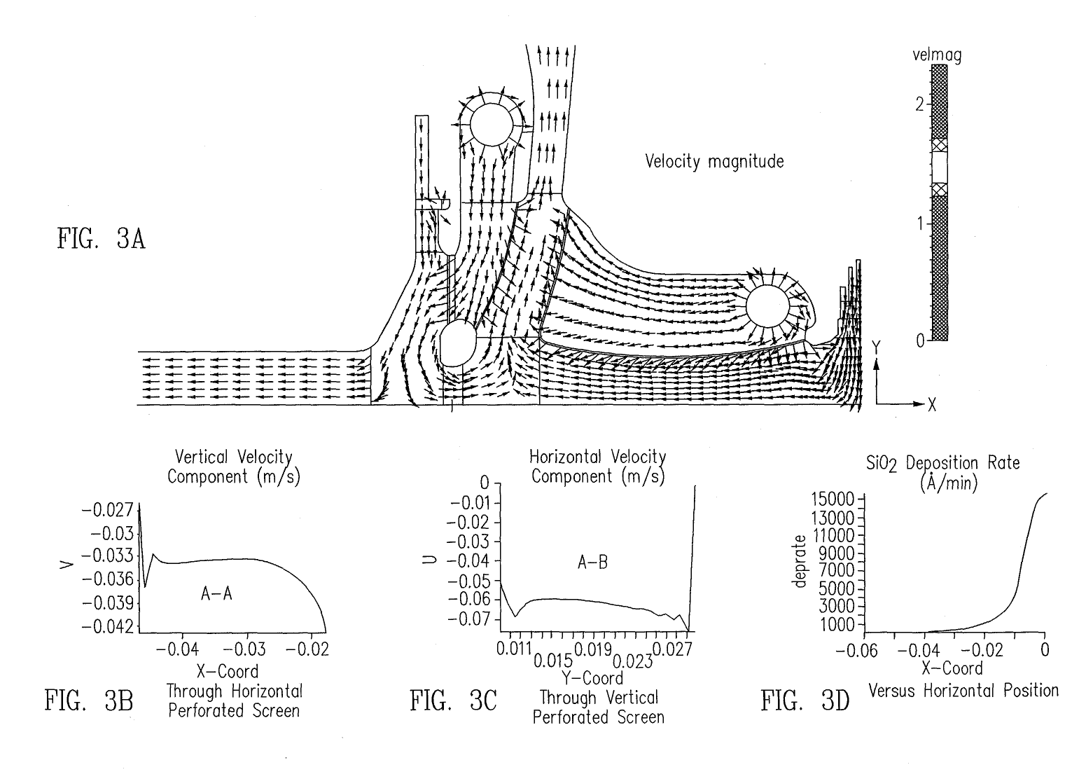

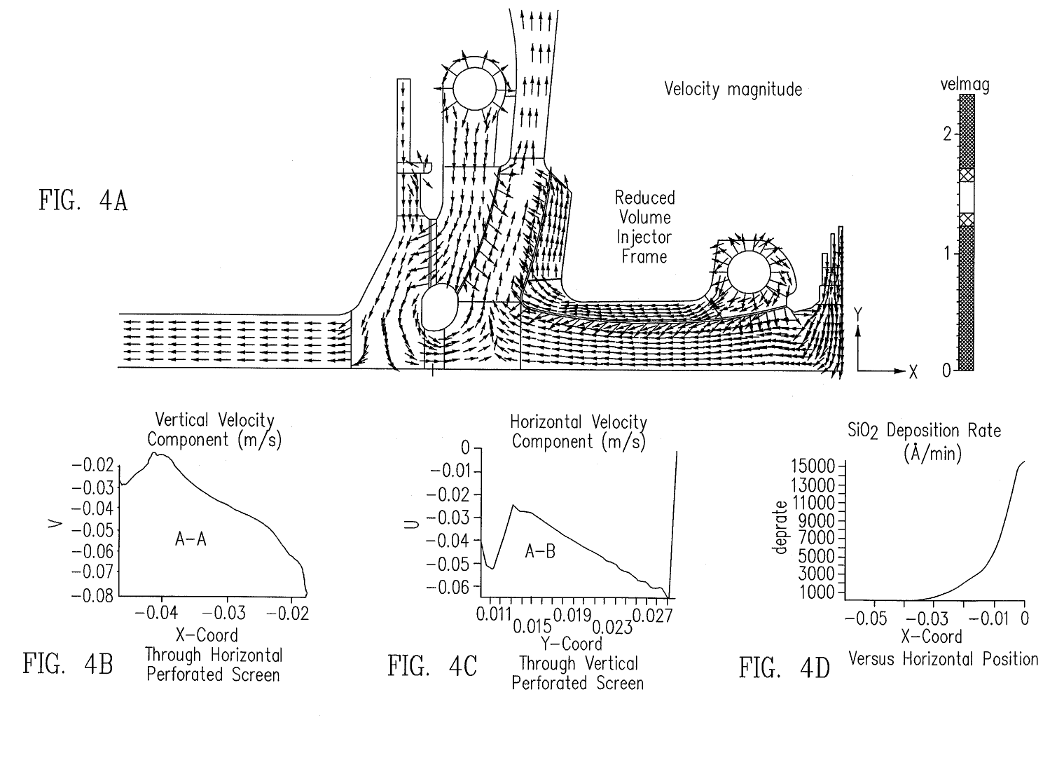

FIGS. 3A to 3D and 4A to 4D show the velocity magnitude distribution of nitrogen (N2) purge gas through a prior art injector shield in comparison to an injector shield having the reduced volume inserts of the present invention by CFD simulation. As shown in FIGS. 3A to 3D, the prior art injector shield provides a large portion of gas flow exiting and protecting the vertical section of the perforated sheet by the shield exhaust port inlet, but is less effective in protecting the horizontal section of the perforated sheet from heavier reaction byproducts build up, especially in the four comers of the perforated sheet. In contrast, as shown in FIGS. 4A to 4D, the injector shield having reduced volume inserts of the present invention provides a greater portion of gas flow exiting and protecting the horizontal section of the perforated sheet, and therefore reducing the reaction byproduct build up directly above the wafer surface and preserving the flow pattern better over time.

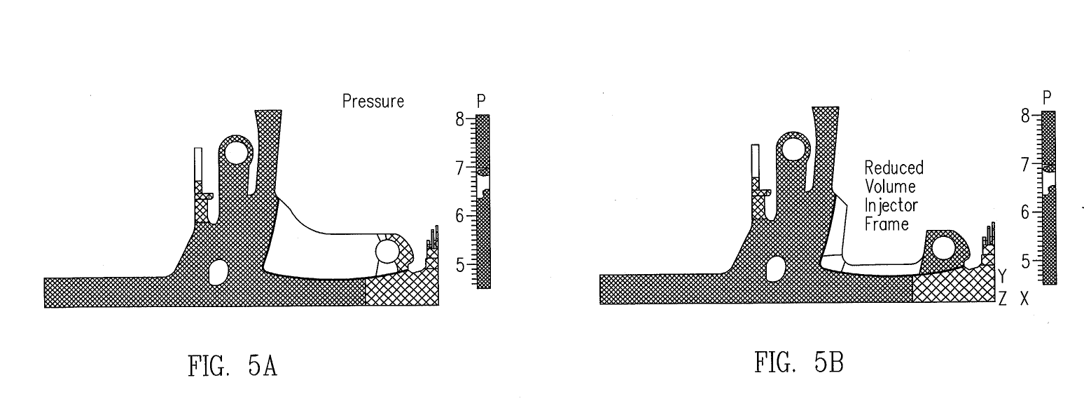

FIGS. 5A and 5B are plots from CFD simulations showing the pressure distribution inside an injector shield frame having the reduced volume inserts of the present invention (FIG. 5B) as compared to the prior art injector shield (FIG. 5A). The pressure distribution inside the injector shield with reduced volume inserts shows a greater value near the metering tube by the injector and a lower value near the exhaust port inlet, corresponding to better protection from incursion of chemicals from the adjacent injector slot through the horizontal section of the perforated sheet. The injector and vent shield flows are 35/35 slm in both simulations. Increasing the injector shield flow can pressurize the entire reduced internal volume of the injector shield body frame higher than that of the prior art injector shield.

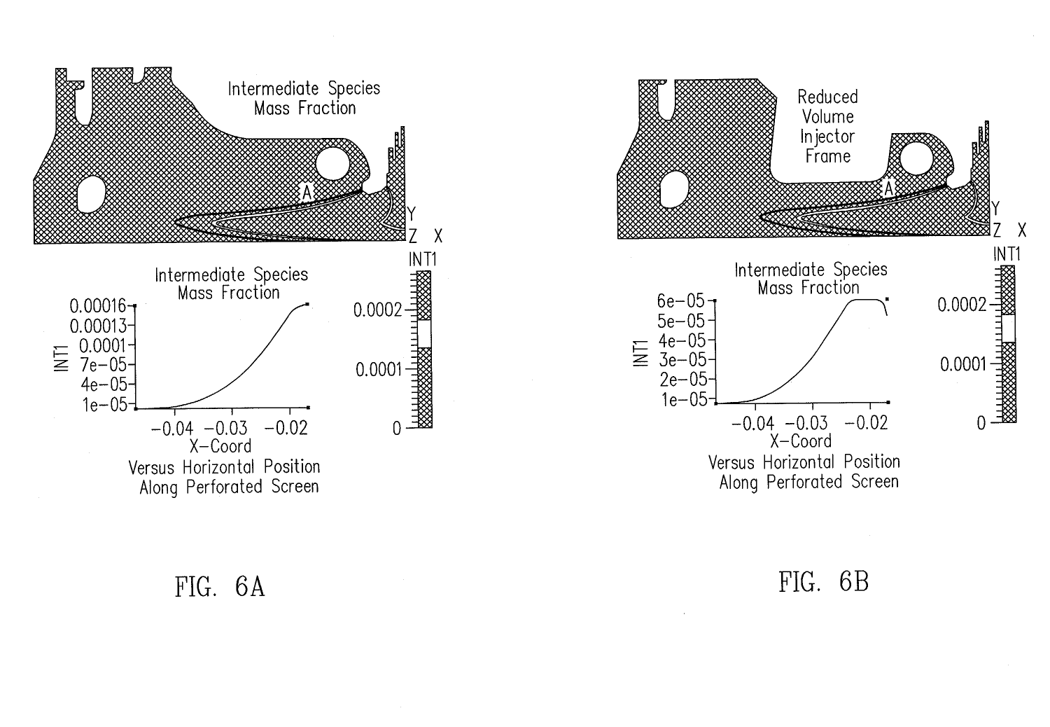

FIGS. 6A and 6B shows the resulting reduction in intermediate chemical reaction species at the surface of the improved injector shield having the volume inserts of the present invention (FIG. 6B) as compared to a prior art injector shield (FIG. 6A). In this silicon oxide deposition model, gaseous chemical reactants tetraethylorthosilicate (TEOS) and ozone (O₃) are used to form silicon dioxide (SiO₂). The mass fraction of intermediate species formed by the TEOS and O₃ reaction is at a higher concentration at the horizontal surface of the injector shield perforated sheet for the prior art injector shield as compared to the injector shield with volume inserts of the present invention. The lower concentration (58%) of reacting chemicals for the present injector shield correlates to a cleaner perforated sheet, also experimentally observed after actual SiO₂ longevity deposition. The present improved shield perforated sheet was free of SiO2 deposits near the injector outlet.

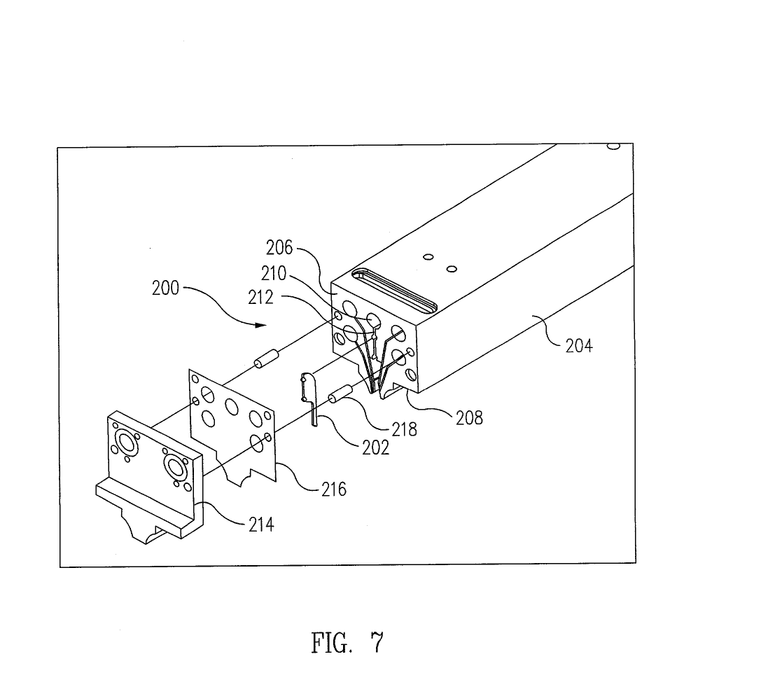

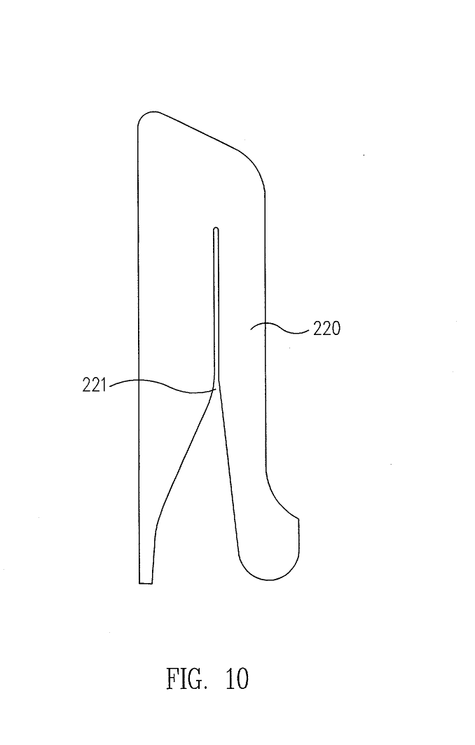

In another embodiment, the present invention provides a chemical vapor deposition system comprising an injector and protective shield. The injector includes injector plugs disposed at the ends of the chemical injection port slot to balance inert purge gas supplied to the ends of the chemical injection slots relative to the other injector flows, thereby reducing deposition and build up of reaction byproducts on the protective shield while still protecting the end plates of the shield of the ends of the injector. An injector having injector plugs is described in detail with reference to FIGS. 7-10.

FIG. 7 shows an exploded view of an injector 200 having injector plugs or chemical plugs 202 of prior art. The injector is formed of an elongated member 204 having end surfaces 206 and a front gas delivery surface 208 extending along the length of the elongated member 204. The elongated member 204 includes a number of elongated passages 210 for delivering chemical and inert gases. Also formed within the elongated member 204 are a number of thin distribution channels or slots 212 which extend between the elongated passages 210 and the front gas delivery surface 208. The distribution channels 212 direct gaseous substances to a region where mixing of the gases is desired to form a thin film on the substrate positioned beneath the injector 200. End caps 214, braze foils 216, alignment pins 218 and chemical plugs 202 are sequentially attached to the elongated member 204. The chemical plugs 202 are inserted at the ends of the chemical distribution channel 212. A more detailed description of the injector can be found in U.S. Pat. No, 5,683,516, which is incorporated hereby in its entirety by reference.

In the prior art, the chemical plugs 202 are of finger shape pointing downwardly. The solid part of the chemical plug blocks chemical flow out of the distribution channel 212. Inert gases such as nitrogen flow through the opening under the solid part of the plug 202 creating an inner purge at the ends of the distribution channel 212. The inert gas purge prevents chemical gas from flowing out of the ends of the distribution channel 212, thus reducing the deposition of reaction byproducts at the end plates of the protective shield adjacent to the ends of the distribution channel.

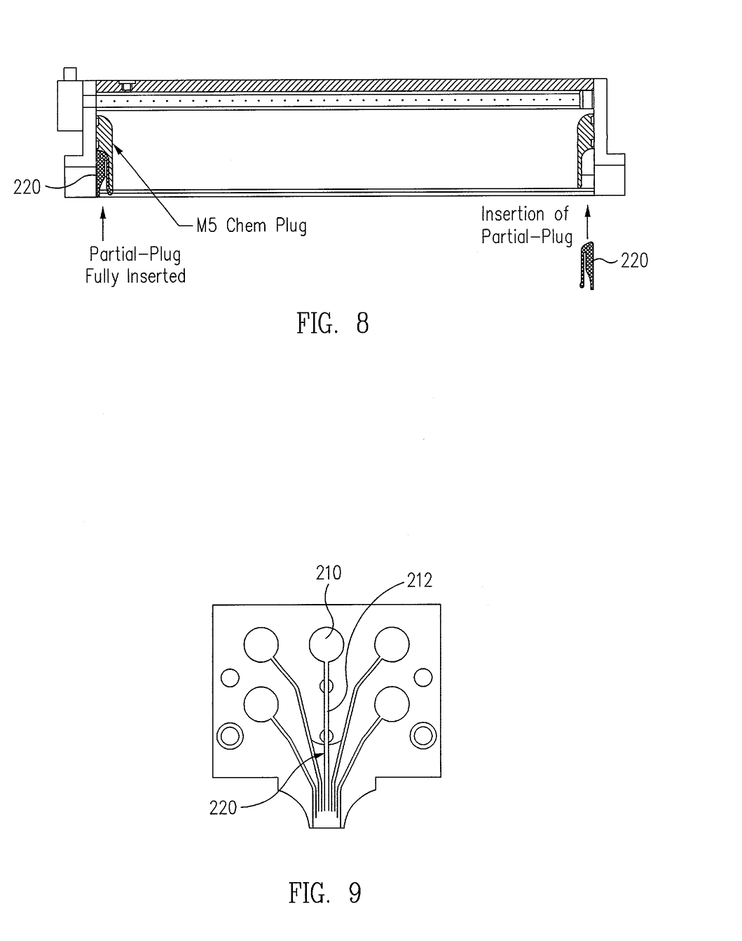

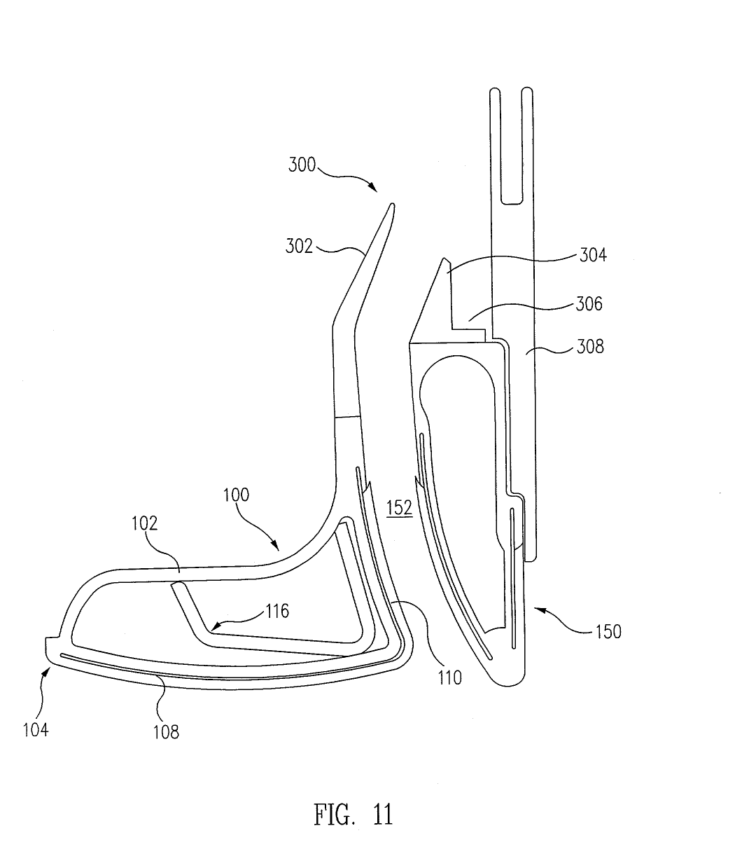

However, high inert gas purge flow which protects the shield plates may concentrate the chemicals that are injected a short distance away from the ends of distribution channel 212, thus causing heavier build-up of reaction byproducts on the four comers of the perforated sheet of the shield. To adjust inert gas flow at the ends of the distribution channels 212, the present invention provides injector partial plugs 220 as shown in one embodiment in FIG. 10. The partial plug 220 is generally comprised of a thin sheet having a slot or opening 221. The slot or opening 221 in the partial plug 220 is varied in dimension to adjust the flow of purge gas. FIGS. 8-10 show one example of a partial plug in detail. As shown in FIGS. 8-10, the dimension of the opening can be very narrow in the upper part, and wide in the lower part adjacent to the front surface of the injector. While one specific example is provided for illustrative purpose, the present invention is not so limited. The shape and dimension of the opening of the partial plugs can be varied to provide inert purge gas at the ends of the chemical slot to reduce deposition of reaction byproducts at both the end plates and four comers of the perforated sheet of the protective shield. For a specific process application, too much flow will protect the shield end plates but cause excessive build-up on the perforated sheet. Too little purge flow will allow more uniform build-up on the perforated sheet but not protect the shield end plates. Thus, the present invention allows one to tailor the balancing of the purge gas flow.

The insertion of partial plugs into the injectors can eliminate excessive buildup of byproducts on the perforated sheet of the injector shield. Insertion of the partial plugs into the ends of the injector chemical distribution channels allows for redirection and metering of inert gas purge flow, thus reducing heavy byproduct buildup on the injector perforated sheet of the shield while still protecting the shield end-plates based on each specific process application.

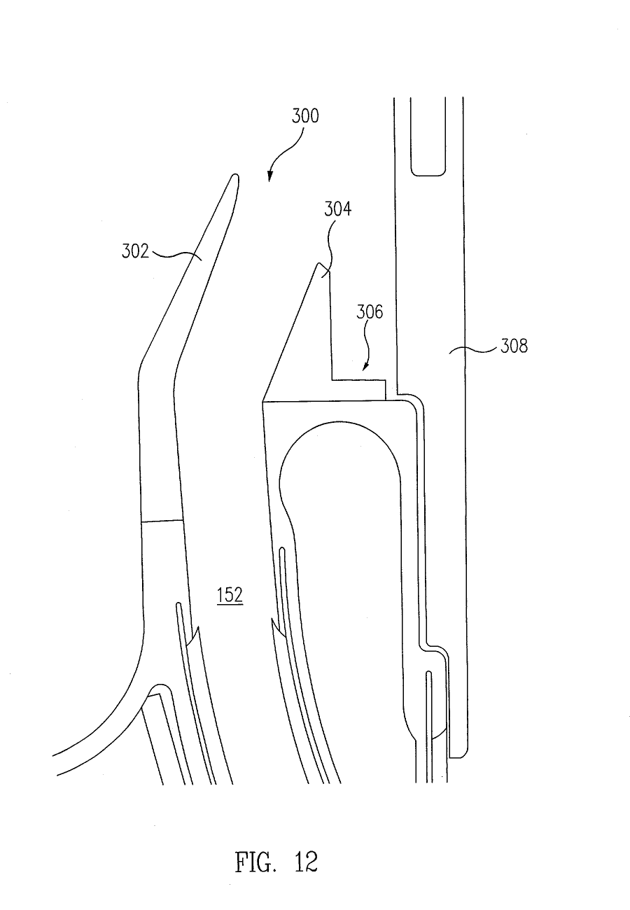

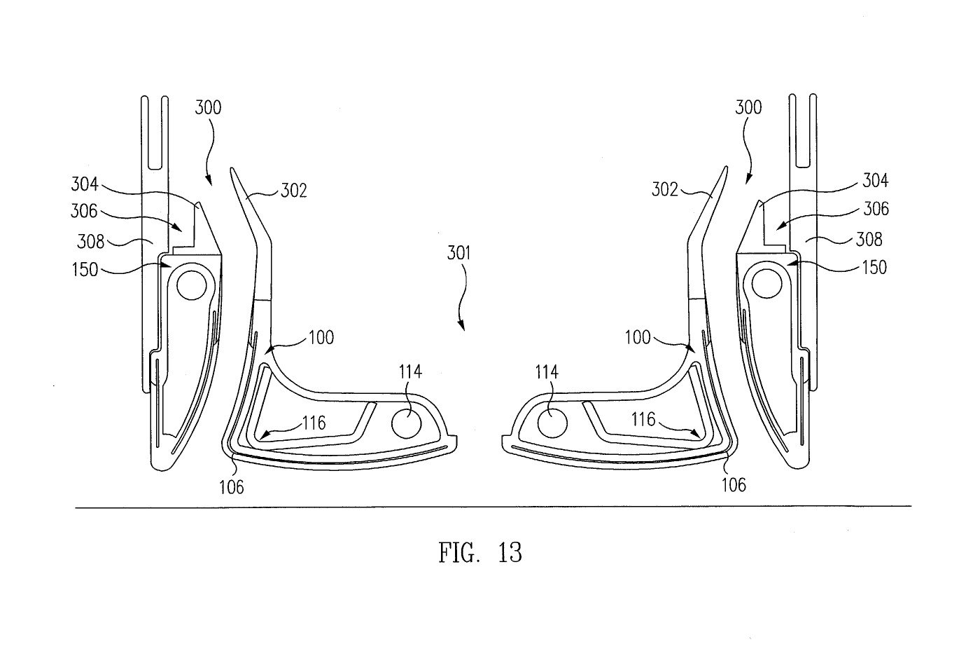

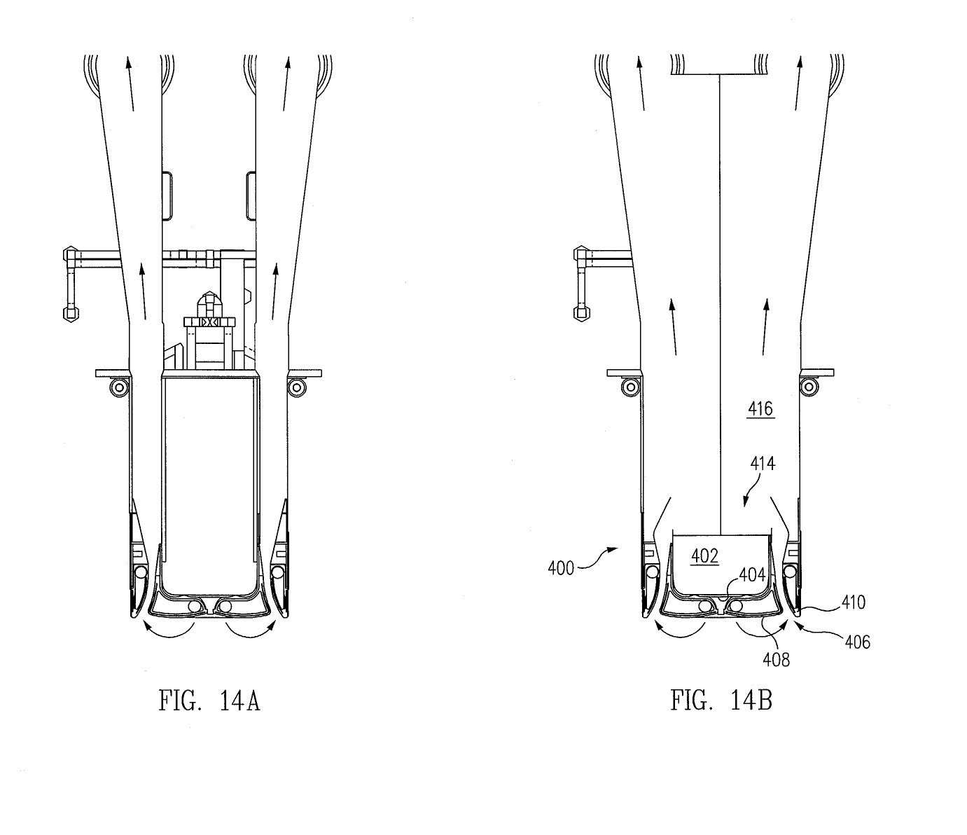

In another embodiment, the protective shield of the present invention provides a vent guide assembly 300 having injector shields 100 and vent shields 150 for directing unused gaseous substances and reaction byproducts to the center of the vent path, thus reducing the quantity of reaction byproducts deposits on the vent shroud walls. The vent guide assembly 300 can also prevent reaction byproduct particles or flakes from falling back onto wafers during processing. The vent guide assembly 300 is described in detail with references to FIGS. 11 to 13. FIG. 13 shows the entire protective shield 301 comprised of pairs of both the injector shield 100 and vent shield 150 of the present invention.

In general, the protective shield 301 including a vent guide assembly 300 comprises a pair of injector shield bodies 100 positioned adjacent to an injector and spaced apart to define a port for flow of reagents from the injector, and a pair of vent shield bodies 150 spaced apart from the injector shield bodies to define exhaust path inlets. A vent guide assembly is provided to channel unused gaseous substances and reaction by-products along the central path of the exhaust port and thus deposition of reaction by-products on the vent shroud walls is reduced.

In particular, referring to FIGS. 11 to 13, where FIG. 11 shows only one side of the protective shield for simplicity, the vent guide assembly 300 includes a first guide member 302 coupled to a injector shield body 100 and a second guide member 304 coupled to the vent shield body 150. The first guide member 302 extends upwardly and outwardly to the vent path (not shown). The extension of the first guide member 302 forms an angle with respect to a vertical axis. The angle can range from about 15 to 30 degrees depending on specific applications. The second guide member 304 is coupled to a vent shield body 150 and extends upwardly and outwardly to the vent path. The extension of the second guide member 304 forms an angle with respect to a vertical axis ranging from about 15 to 30 degrees. The first and second guide members 302 and 304 are configured to form an outwardly curved section of the exhaust port inlet to direct reaction by-products to the center of the exhaust path away from cooler vent shroud walls in the exhaust path, whereby deposits of reaction byproducts on the vent shroud walls are reduced. Preferably the first and second guide members 302 and 304 extend upwardly and outwardly in parallel and at an angle with respect to a vertical axis from about 15 to 30 degrees.

The first guide member 302 can be an integral part of the base frame 104 of the injector shield body 100. In this case, the base frame 104 of the injector shield body 100 extends upwardly and bends outwardly at an angle with respect to the vertical section. The second guide member 304 can also be machined to be an integral part of the vent shield body 150.

To prevent any deposits or flakes from falling back onto wafers, it is preferred that the second guide member 304 is machined so that a recess 306 is formed between the second guide member 304, the vent shield body 150, and a side plate 308 that connects the vent shield body 150 to the vent shroud outer walls. Accordingly any deposits or flakes from the vent shroud outer walls are trapped in the recess 306 and prevented from falling back onto the wafer in process. Similarly, the outwardly bending section of the first guide member 302 can also function as a physical trap that prevent any deposits and flakes from vent shroud inner walls from falling back onto the wafer in process.

In an injector shield without the vent guide assembly, powdery deposits in the vent shroud may flake from the walls of the exhaust path and drop directly back onto the wafers in process. In contrast, the protective shield and vent guide assembly of the present invention directs or channels the unused gaseous substances and reaction byproducts through the center of the vent shroud exhaust path. This redirection of the exhaust gases reduces the quantity of powder deposits on the vent shroud walls, thus minimizing the quantity of material available to flake off. Also, the vent guide assembly forms physical trap areas such that if powders or flakes drop from the vent walls, they are caught in the trap areas and prevented from falling back onto the wafers in process.

Previous exhaust routing directs the reaction by-products exiting the shield exhaust path inlet into a larger volume at lower velocity against the cooler vent shroud walls such that powdery deposits form on the cool walls. The vent guide assembly of the present invention redirects the exhaust gases to the center of the exhaust path away from the cooler vent shroud walls without much reduction in velocity. The vent guide assembly surfaces, which may be extensions of the hotter shield frames, are at a sufficiently high temperature (about 225-275° C.) such that by-products do not form powdery deposits on the guides. The formation of powdery deposits occurs further away at a greater height beyond the assembly guided path. This removes concentrated reaction by-products to the trap areas where any flakes from the vent shroud walls are more likely to fall harmlessly in the trap space rather than falling back onto the wafers in process. In addition to reducing the total amount of powder accumulation on the closer vent shroud walls, the accelerated velocity of the exhaust flow through the vent guide assembly better deflects falling powder or flakes dropping from the vent walls. In this way flakes are prevented from falling back onto the wafers in process.

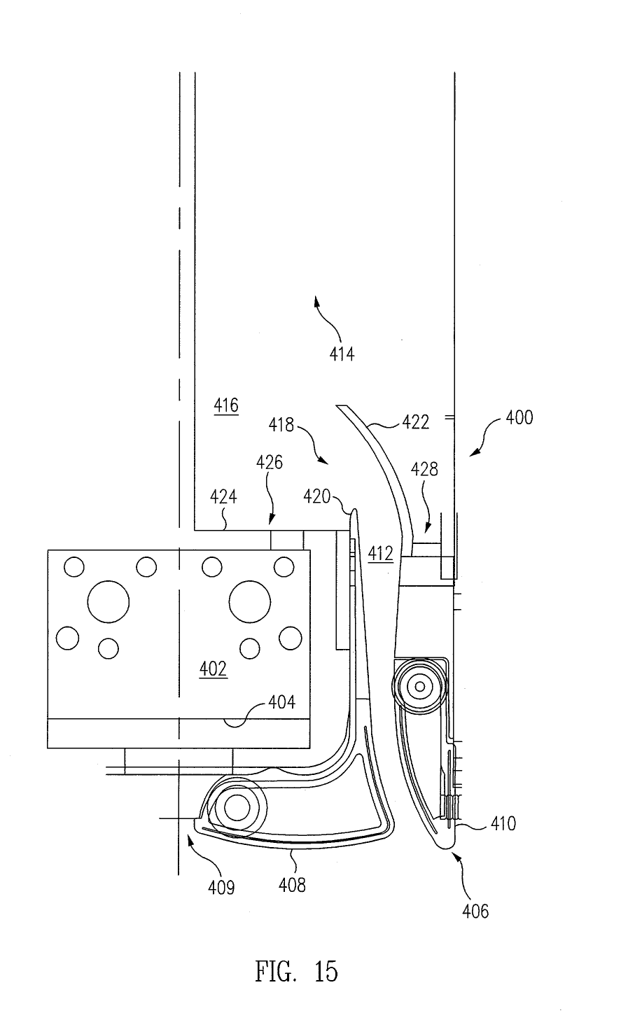

In another embodiment, the present invention provides a CVD system with one or more deposition chambers having a full volume vent assembly 400 to create a large powder trap volume, thereby enhancing the run time before any cleaning maintenance is required. The CVD system having a full volume vent assembly 400 are now described with references to FIGS. 14-16.

In general, the chemical vapor deposition system with full volume vent assembly 400 comprises an injector body 402 having a front surface 404 formed with one or more ports 409 for injecting gaseous substances. A shield assembly 406 is provided for protecting the front surface 409 of the injector. The shield assembly 406 comprises a pair of injector shield bodies 408 positioned adjacent the injector 402 and spaced apart to define a port 409 for flow of the gaseous substances from the injector 402, and a pair of vent shield bodies 410 spaced apart from each of said injector shield bodies 408 to define an exhaust path inlet 412. A full volume vent shroud 414 is provided for removing unused gaseous substances and reaction by-products from the reaction chamber. The vent shroud 414 comprises a pair of exhaust path inlets 412 defined by the injector shield and vent shield bodies 406 and 408. The exhaust path inlets 412 extend at least above the height of the injector body 402. A pair of vent paths 416 are provided above the injector 424. The vent paths 416 encompass substantially the full length and width of the injector body 402.

FIGS. 14-16 schematically show the details of a CVD system having the full volume vent assembly 400. FIG. 14 shows a comparison of the full volume vent assembly 400 to a prior art vent assembly. The vent paths 416 encompass substantially the full width and length of the injector body 402. This is in contrast to the prior art vent system where the vent paths are defined by the inner and outer vent shroud walls which do not encompass the width and length of the injector.

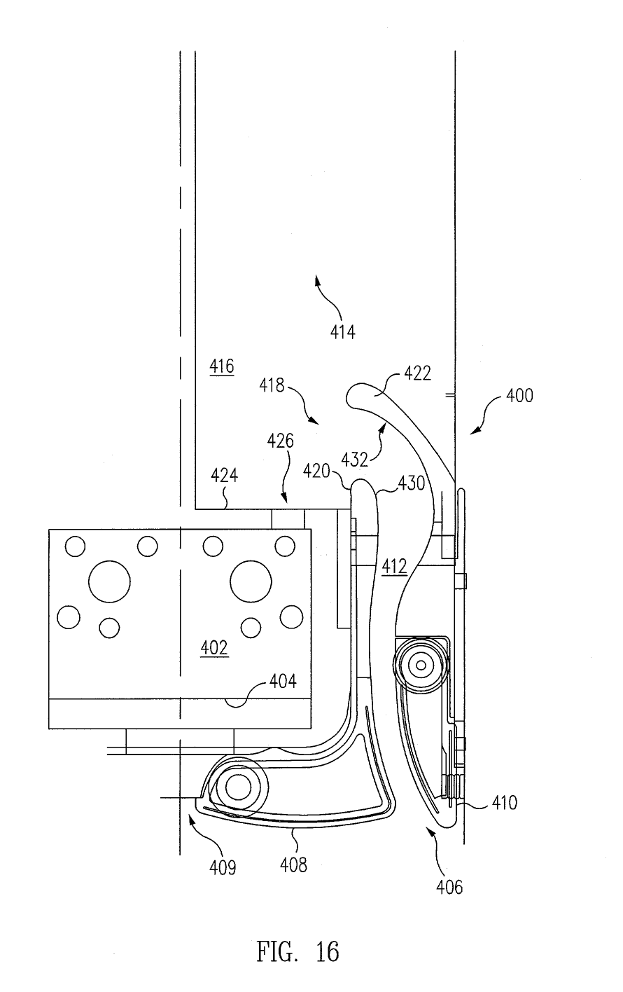

The protective shield 406 is formed of injector shield bodies 408 and vent shield bodies 410 which have extensions above the height of the injector 402 as shown in FIG. 15. The protective shield 406 comprises a vent guide assembly 418 which includes a first guide member 420 provided to the injector shield body 408 and extending upwardly above the height of the injector 402. A second guide member 422 is provided to the vent shield body 410. The second guide member 422 comprises a curved section extending upwardly and inwardly into the vent path 416. Consequently, the first and second guide members 420 and 422 define a curved stretch of the exhaust port inlet extending upwardly and inwardly into the vent path 416.

Preferably the second guide member 422 extends upwardly and inwardly across and over the first guide member 420 such that there is no vertical access for any powdery deposits from the vent path 416 to fall directly to the wafer in process through the exhaust port inlet 412. The injector 402 is preferably connected to the vent paths 416 through a baffle 424. The first guide member 420 extends above the baffle 424. A large physical trap area 426 is defined by the inner wall of the vent path 416, the baffle 424 and the first guide member 420. The first guide member 420 extends above the baffle 424 in a minimum height to form a physical trap area 426 sufficient to trap any powdery deposits or flakes falling back from the inner wall of the vent path 416.

Preferably the second guide member 422 is machined such that a physical trap area 428 is formed between the second guide member 422, the outer wall of the vent path 416 and the vent shield body 410. Any powder deposits or flakes falling off from the outer wall of the vent path 416 are received in the physical trap 428.

The CVD system having the full volume vent assembly 400 is advantageous in that there is no vertical access for powdery deposits or flakes to fall back onto the wafer from the vent paths 416 since the second vent guide member extends laterally across over the first guide member. Further, the widest lateral geometry of the injector available may be used to create a much larger powder-trap volume. This enhances the run time before any cleaning maintenance is required from the vent walls, thereby minimizing the susceptibility of the system to gravity driven powder or flake drops onto the wafers in process.

FIG. 16 shows another embodiment of the full volume vent assembly, incorporating an inert gas purged vent guide assembly to reduce glassy or powdery deposits in the exhaust port inlet 412. In this embodiment, the internal volume of injector shield bodies 408 and vent shield bodies 410 is extended upward to allow purge gas flow out additional perforated sheets 430 and 432 incorporated into the inner surfaces of the first and second guide members 420 and 422 respectively. The CVD system having the full volume vent assembly with the inert gas purged vent guide is advantageous in that the complete exhaust path from the injector up into the large volume vent shroud is better purged to further reduce potential particulate contamination on wafers in process below.

The foregoing description of specific embodiments and examples of the invention have been presented for the purpose of illustration and description, and although the invention has been illustrated by certain of the preceding examples, it is not to be construed as being limited thereby. They are not intended to be exhaustive or to limit the invention to the precise forms disclosed, and obviously many modifications, embodiments, and variations are possible in light of the above teaching. All or some of the above embodiments may be combined for process advantage. It is intended that the scope of the invention encompass the generic area as herein disclosed, and by the claims appended hereto and their equivalents.

What is claimed is:

1. A protective shield for gas distribution systems, comprising:
a base having a unit frame formed around the perimeter of the base;
a perforated sheet carried by the unit frame, said perforated sheet having a horizontal section facing a substrate, and a vertical section facing an exhaust port;
a plenum partially defined by the base and the horizontal and vertical sections of the perforated sheet;
a gas delivery device for delivering an inert gas to the plenum at a flow rate such that the gas diffuses through the perforated sheet; and
a volume insert disposed within the plenum for controlling distribution of the gas flowing through the horizontal and vertical sections of the perforated sheet.

2. The protective shield of claim 1 wherein the volume insert is a bent band coupled to the base and disposed within the plenum such that the internal volume of the plenum for gas flow is reduced, and distribution of the gas flow to the horizontal section is increased sufficiently to prevent incursion of external gases inside the shield and to form a suitable boundary layer which substantially eliminates deposits on the horizontal section of the perforated sheet.

3. The protective shield of claim 2 wherein the volume insert is a three-bend band extending the full length of the base, the three-bend band has a first surface facing the vertical section of the perforated sheet, a second surface facing the horizontal section of the perforated sheet, and a third surface facing the gas delivering device, wherein the second surface of the three bend band and the horizontal section of the perforated sheet forms a passageway tapering from wide to narrow as the gas flows from the gas delivering device along the horizontal section to the vertical section of the perforated sheet.

4. A chemical vapor deposition system comprising:
an injector having a front surface for injecting gaseous substances into a processing chamber; and
a protective shield positioned adjacent the injector for protecting the front surface of the injector, said protective shield comprising end plates and perforated sheets;
wherein the injector comprises:
a chemical injection port slot for injecting gaseous substances into said processing chamber; and
injector plugs disposed at the ends of the chemical injection port slot to balance inert purge gas supplied to the ends of the chemical injection port slot relative to a chemical gas supplied to the middle of the chemical injection port slot, wherein deposition and buildup of reaction byproducts on the perforated sheets are reduced without allowing substantial deposition build-up on the end plates.

5. The chemical vapor deposition system of claim 4 wherein the injector plug is provided with an opening varying in dimension which restricts the inert purge gas flow supplied to the ends of the chemical injection port slot, said opening comprises a first narrow section and a second wide section adjacent the front surface of the injector.

6. The chemical vapor deposition system of claim 4 or 5 wherein the protective shield comprises:
a base having a unit frame formed around the perimeter of the base;
a perforated sheet carried by the unit frame, said perforated sheet having a horizontal section facing a substrate, and a vertical section facing an exhaust port;
a plenum partially defined by the base and the horizontal and vertical sections of the perforated sheet;
a gas delivery device for delivering an inert gas to the plenum at a flow rate such that the gas diffuses through the perforated sheet; and
a volume insert disposed within the plenum for controlling distribution of the gas flow through the horizontal and vertical sections of the perforated sheet.

7. The chemical vapor deposition system of claim 6 wherein the volume insert is a bent band coupled to the base and disposed within the plenum such that the internal volume of the plenum for gas flow is reduced, and distribution of the gas flow to the horizontal section is increased sufficiently to prevent incursion of external gases inside the shield and to form a suitable boundary layer which substantially eliminates deposits on the horizontal section of the perforated sheet.

8. The chemical vapor deposition system of claim 7 wherein the volume insert is a three-bend band extending the full length of the base, the three-bend band has a first surface facing the vertical section of the perforated sheet, a second surface facing the horizontal section of the perforated sheet, and a third surface facing the gas delivering device, wherein the second surface of the three bend band and the horizontal section of the perforated sheet forms a passageway tapering from wide to narrow as the gas flows from the gas delivering device along the horizontal section to the vertical section of the perforated sheet.

9. A protective shield assembly for a gas distribution system, comprising:
a pair of injector shield bodies positioned adjacent an injector and spaced apart to define a port there between for flow of gaseous substances from the injector,
a pair of vent shield bodies spaced apart from said injector shield bodies, wherein said vent shield and injector shield bodies define an exhaust path inlet for exhausting unused gaseous substances and reaction byproducts; and
a pair of vent guide assemblies for directing the unused gaseous substances and reaction byproducts from the exhaust path inlet to a vent path, wherein each vent guide assembly comprises:
a first guide member coupled to the injector shield body and extending upwardly and outwardly to the vent path; and
a second guide member coupled to the vent shield body and extending upwardly and outwardly to the vent path;
wherein the first and second guide members are configured to form an outwardly curved section of the exhaust path inlet to direct the unused gaseous substances and reaction byproducts toward the center of the vent path to reduce deposition of unused gaseous substances and reaction byproducts on walls of the vent path.

10. The protective shield assembly of claim 9 wherein said first guide member is an integral part of the injector shield body and said second guide member is an integral part of the vent shield body, and said first and second guide members extend upwardly and outwardly substantially in parallel and at an angle from a vertical axis between about 10 to 30 degrees.

11. The protective shield assembly of claim 10 further comprising a pair of side plates for connecting the vent shield bodies to the walls of the vent paths, wherein said side plate, second guide member, and vent shield body form a recess to receive particle deposits, and said first guide member extends upwardly and outwardly to form a trap area to receive particle deposits.

12. The protective shield assembly of claim 9, 10 or 11 wherein the injector shield further comprises:
a base having a unit frame formed around the perimeter of the base;
a perforated sheet carried by the unit frame, said perforated sheet having a horizontal section facing a substrate, and a vertical section facing an exhaust port;
a plenum partially defined by the base and the horizontal and vertical sections of the perforated sheet;
a gas delivery device for delivering an inert gas to the plenum at a flow rate such that the gas diffuses through the perforated sheet; and
a volume insert disposed within the plenum for controlling distribution of the gas flow through the horizontal and vertical sections of the perforated sheet.

13. The protective shield assembly of claim 12 wherein the volume insert is a three-bend band extending the full length of the base, and the three-bend band has a first surface facing the vertical section of the perforated sheet, a second surface facing the horizontal section of the perforated sheet, and a third surface facing the gas delivering device, wherein the second surface of the three bend band and the horizontal section of the perforated sheet forms a passageway tapering from wide to narrow as the gas flows from the gas delivering device along the horizontal section to the vertical section of the perforated sheet.

14. A chemical vapor deposition system, comprising,
an injector body having a front surface formed with a port for injecting gaseous substances, and a back surface for connecting to a vent assembly;
a shield assembly for protecting the front surface of the injector, said shield assembly comprises
a pair of injector shield bodies positioned adjacent the injector body and spaced apart to define a port there between for flow of the gaseous substances from the injector; and
a pair of vent shield bodies spaced apart from each of said injector shield bodies, wherein each of said vent shield bodies and injector shield bodies defines an exhaust path inlet; and
a full volume vent assembly for removing unused gaseous substances and reaction by-products from the reaction chamber, said vent assembly comprises:
a pair of exhaust path inlets defined by the injector shield and vent shield bodies, said exhaust path inlets extending at least above the height of the injector body; and
a pair of vent paths provided above the injector and encompassing substantially the full length and width of the injector body.

15. The chemical vapor deposition system of claim 14 wherein said shield assembly further comprises:
a vent guide assembly including:
a first guide member coupled to the injector shield body and extending upwardly above the back surface of the injector body; and
a second guide member coupled to the vent shield body, said second guide member comprises a curved section extending upwardly and inwardly into the vent path;
wherein said first and second guide members define a curved section of the exhaust port inlet extending upwardly and inwardly into the vent path, and inner and outer walls,
wherein the first guide member of the injector shield extends upwardly above the height of the injector to form a trap area between the inner wall, the first guide member, and the injector,
wherein the vent shield body, the second guide member and the outer wall of the full volume vent assembly form a recess for receiving particle deposits, and
wherein the second guide member extends upwardly and inwardly across over the first guide member such that there is no direct access for any particle deposits to the substrate through the exhaust port inlet.

16. The chemical vapor deposition system of claim 14 or 15 wherein the first and second guide members are provided with plenums partially defined by perforated sheets that line the entrance to the full volume vent, and inert gas is supplied to the plenums and diffuses through the perforated sheets of the first and second guide members.

17. A chemical vapor deposition system comprising:
an injector having a front surface for injecting gaseous substances into a processing chamber, said injector comprises:
a chemical injection port slot for injecting gaseous substances into said processing chamber; and
injector plugs disposed at the ends of the chemical injection port slot to balance inert purge gas flow supplied to the ends of the chemical injection port slot relative to a chemical gas flow supplied to the middle of the chemical injection port slot; and
a shield assembly for protecting the front surface of the injector, said shield assembly comprising:
a pair of injector shield bodies positioned adjacent the injector and spaced apart to define a port there between for flow of gaseous substances from the injector,
wherein each injector shield body comprises
a base having a unit frame formed around the perimeter of the base;
a perforated sheet carried by the unit frame, said perforated sheet having a horizontal section facing a substrate, and a vertical section facing an exhaust port;
a plenum partially defined by the base and the horizontal and vertical sections of the perforated sheet;
a gas delivery device for delivering an inert gas to the plenum at a flow rate such that the gas diffuses through the perforated sheet; and
a volume insert disposed within the plenum for controlling distribution of the gas flow through the horizontal and vertical sections of the perforated sheet;
a pair of vent shield bodies spaced apart from said injector shield bodies,
wherein said vent shield and injector shield bodies define an exhaust path inlet for collecting unused gaseous substances and reaction byproducts; and
a pair of vent guide assemblies for directing the unused gaseous substances and reaction byproducts from the exhaust path inlet to a vent path, wherein each vent guide assembly comprising:
a first guide member coupled to the injector shield body and extending upwardly and outwardly to the vent path; and
a second guide member coupled to the vent shield body and extending upwardly and outwardly to the vent path;
wherein the first and second guide members configured to form an outwardly curved section of the exhaust path inlet to direct the unused gaseous substances and reaction byproducts to the center of the vent path.

18. The chemical vapor deposition system of claim 17 wherein the volume insert is a bent band coupled to the base and disposed within the plenum such that the internal volume of the plenum for gas flow is reduced, and distribution of the gas flow to the horizontal section is increased sufficiently to prevent incursion of external gases inside the shield and to form a suitable boundary layer which substantially eliminates deposits on the horizontal section of the perforated sheet.

19. The chemical vapor deposition system of claim 18 wherein the volume insert is a three-bend band extending the full length of the base, the three-bend band has a first surface facing the vertical section of the perforated sheet, a second surface facing the horizontal section of the perforated sheet, and a third surface facing the gas delivering device, wherein the second surface of the three bend band and the horizontal section of the perforated sheet forms a passageway tapering from wide to narrow as the gas flows from the gas delivering device along the horizontal section to the vertical section of the perforated sheet.

20. The chemical vapor deposition system of claim 17 wherein the injector plug is provided with an opening varying in dimension which restricts the inert purge gas flow supplied to the ends of the chemical injection port slot, said opening comprises a first narrow section and a second wide section adjacent the front surface of the injector.

21. The chemical vapor deposition system of claim 17 wherein said first guide member is an integral part of the injector shield body and said second guide member is an integral part of the vent shield body, and said first and second guide members extend upwardly and outwardly substantially in parallel and at an angle from a vertical axis between about 10 to 30 degrees.

22. The protective shield assembly of claim 17 further comprising a pair of side plates for connecting the vent shield bodies to the walls of the vent paths, wherein said side plate, second guide member, and vent shield body form a recess to receive particle deposits, and said first guide member extends upwardly and outwardly to form a trap area to receive particle deposits.

23. A chemical vapor deposition system comprising:
an injector having a front surface for injecting gaseous substances into a processing chamber, said injector comprises:
a chemical injection port slot for injecting gaseous substances into said processing chamber; and
injector plugs disposed at the ends of the chemical injection port slot to balance inert purge gas flow supplied to the ends of the chemical injection port slot relative to a chemical gas flow supplied to the middle of the chemical
injection port slot;
a shield assembly for protecting the front surface of the injector, said shield assembly comprising:
a pair of injector shield bodies positioned adjacent the injector and spaced apart to define a port there between for flow of gaseous substances from the injector,
wherein each injector shield body comprises
a base having a unit frame formed around the perimeter of the base;
a perforated sheet carried by the unit frame, said perforated sheet having a horizontal section facing a substrate, and a vertical section facing an exhaust port;
a plenum partially defined by the base and the horizontal and vertical sections of the perforated sheet;
a gas delivery device for delivering an inert gas to the plenum at a flow rate such that the gas diffuses through the perforated sheet; and
a volume insert disposed within the plenum for controlling distribution of the gas flow through the horizontal and vertical sections of the perforated sheet;
a pair of vent shield bodies spaced apart from said injector shield bodies,
wherein said vent shield and injector shield bodies define an exhaust path inlet for collecting unused gaseous substances and reaction byproducts; and
a full volume vent assembly for removing unused gaseous substances and reaction by-products from the reaction chamber, said vent assembly comprises:
a pair of exhaust path inlets defined by the injector shield and vent shield bodies, said exhaust path inlets extending at least above the height of the injector body; and
a pair of vent paths provided above the back surface of the injector and encompassing substantially the full length and width of the injector body.

24. The chemical vapor deposition system of claim 23 wherein the volume insert is a bent band coupled to the base and disposed within the plenum such that the internal volume of the plenum for gas flow is reduced, and distribution of the gas flow to the horizontal section is increased sufficiently to prevent incursion of external gases inside the shield and to form a suitable boundary layer which substantially eliminates deposits on the horizontal section of the perforated sheet.

25. The chemical vapor deposition system of claim 24 wherein the volume insert is a three-bend band extending the full length of the base, the three-bend band has a first surface facing the vertical section of the perforated sheet, a second surface facing the horizontal section of the perforated sheet, and a third surface facing the gas delivering device, wherein the second surface of the three bend band and the horizontal section of the perforated sheet forms a passageway tapering from wide to narrow as the gas flows from the gas delivering device along the horizontal section to the vertical section of the perforated sheet.

26. The chemical vapor deposition system of claim 23 wherein the injector plug is provided with an opening varying in dimension along the injection port slot in the direction of gas flow, said opening comprises a first narrow section and second wide section adjacent to the front surface of the injector.

27. The chemical vapor deposition system of claim 23 wherein the first and second guide members are provided with plenums partially defined by perforated sheets that line the entrance to the full volume vent, and inert gas is supplied to the plenums and diffuses through the perforated sheets of the first and second guide members.
